(19) United States
(12) Patent Application Publication
(10) Pub. No.: US 2012/0031488 A1
(43) Pub. Date: Feb. 9, 2012

(54) PHOTOVOLTAIC CELL MODULE ASSEMBLY

(75) Inventors: William E.S. KAUFMAN, Berkeley Heights, NJ (US); Thomas C. Russell, Murray Hill, NJ (US)

(73) Assignee: WattLots LLC, Milling ton, NJ (US)

(21) Appl. No.: 13/204,363

(22) Filed: Aug. 5, 2011

Related U.S. Application Data
(60) Provisional application No. 61/371,485, filed on Aug. 6, 2010.

(51) Int. Cl. H01L 31/0203

(52) U.S. Cl. 136/259

(57) ABSTRACT

A photovoltaic module comprises an elongated base member having first and second extensions shaped to define an elongated support plane along ends thereof, the elongated support plane extending in a direction of elongation for the elongated base member. The photovoltaic module also includes at least one photovoltaic cell assembly positioned at the ends of the elongated base member, extending generally along the elongated support plane. The elongated base member and the at least one photovoltaic cell assembly define a volume of space therein.

This application claims priority to U.S. Provisional Patent Application Ser. No. 61/371,485, incorporated herein in its entirety by reference.

### FIELD OF THE INVENTION

The present invention relates to mountings for photovoltaic elements.

### BACKGROUND OF THE INVENTION

There are many places on the Earth that cover significant amounts of surface area, but lack any appreciable need for complete open-air exposure. As an example, open air parking lots, or the uppermost level of parking garage buildings, are both exposed areas where people may only be for a short time, before heading into whichever building(s) the parking lots or garages service, and thus would not generally desire complete sunlight exposure. In the context of parking lots, reduced sunlight exposure may indeed be beneficial to reduce the increase in interior car temperature as a vehicle sits in direct sunlight. Other places, such as the rooftops of some buildings (in particular commercial buildings), may seldom or never be visited, or even seen, by those wishing to have direct views of the sky. In yet other places, such as the ponds of water/sewage treatment plants, it may be desirable to reduce external visibility of such surfaces for aesthetic purposes, or to make better use of an otherwise open space.

Any such open-air surface area is exposed to massive amounts of solar radiation, and represents a significant opportunity for solar energy generation. Environmental, economical, or other considerations may make the installation of photovoltaic cells at such areas desirable. The possibility of capturing solar energy radiating on such exposed areas creates the possibility of offsetting operating expenses for property owners (for example by reducing dependence on electricity provided by utility companies), or even may be profit generating (if sufficient electricity is produced such that an excess may be sold). Moreover, irrespective of the potential financial benefits, the ability to take advantage of this open-air space to generate electricity by solar cell technology is entirely environmentally positive. Specifically, the electricity generated will have no carbon emissions, and takes advantage of open-air space that already exists, thus avoiding intrusion into undeveloped areas, which is often the case with large solar cell farms.

Numerous mounting styles exist for solar cell technologies to capture solar energy radiating onto open-air spaces. Because large-scale photovoltaic cells are typically substantial in both size and weight, mountings for such cells may be equally impressive. In many cases, such as when cells are installed onto the rooftops of buildings, the mountings may be close to the rooftop, or may be laid on the rooftop surface itself. One potential issue with such mountings are, of course, the loss of access to structure beneath the photovoltaic cells, which on most commercial buildings may include HVAC compressors or other mechanical accoutrements. In the above examples, where the open space is typically used for parking, some mounting that suspends the photovoltaic cells above the vehicles increases efficient space usage (see, e.g., U.S. patent application Ser. No. 12/537038, the entirety of which is incorporated by reference).

In some conventional photovoltaic mounting systems, large flat canopy structures are used to support a large array of rigid wide format solar panels. While this may effectively provide the solar energy generating functionality, such structures are poorly suited for use in an exposed outdoor environment. Specifically, such large flat canopy structures can create a significant amount of lift or downward force under high wind conditions. As such, the support structure and associated connections must be overdesigned to ensure sufficient stability and strength to withstand such forces. Also, in Northern regions, snow or ice may gather on these structures, significantly adding to their weight (these roof structures are also typically oriented at a specific angle to the sun creating limitations and concentrating water run-off to one end of the structure where it needs to be captured and diverted). This results in a structure that is significantly more expensive, and may also be aesthetically unsightly.

Accordingly, the present inventor has recognized a long-felt but unresolved need for an improved photovoltaic cell mounting structure that functions to effectively capture solar radiation for conversion to electricity, yet has a structural design is lighter, and which may be elevated across a long span.

### SUMMARY OF THE INVENTION

One aspect of the invention provides a photovoltaic module having an elongated base member with first and second extensions shaped to define an elongated support plane along ends thereof. The elongated support plane extends in a direction of elongation for the elongated base member. The photovoltaic module further comprises at least one photovoltaic cell assembly positioned at the ends of the elongated base member, extending generally along the elongated support plane. The elongated base member and the at least one photovoltaic cell assembly define a volume of space therein.

Another aspect of the invention provides a photovoltaic module comprising an elongated base member having a partially tubular configuration with a longitudinally extending opening. The modules further comprises an elongated photovoltaic cell assembly comprising a rigid backing member mounted to the base member to cover the longitudinally extending opening and form a tubular member with the base member. The photovoltaic cell assembly further comprises a plurality of photovoltaic elements mounted to an outer surface of the backing member, and a transparent protective layer coated over the photovoltaic elements. The photovoltaic module further comprises at least one terminal coupled to the photovoltaic elements for conducting of electricity generated by the photovoltaic elements.

Another aspect of the invention provides a photovoltaic cell system comprising a plurality of cables extending across a span. The system further includes a pair of support structures arranged in spaced apart relation from one another and configured to elevate and secure the plurality of cables above the span. The system additionally includes a plurality of elongated photovoltaic modules, each connected to and extending across at least two of said plurality of cables. The system further provides for one or more photovoltaic elements, each supported by one or more of said plurality of elongated photovoltaic modules

Other objects, features, and advantages of the present invention will become apparent from the following detailed description, the appended claims, and the accompanying drawings.

### BRIEF DESCRIPTION OF DRAWINGS

FIG. 1 is a perspective view of a photovoltaic cell system comprising a plurality of cables extending over and above a span, so as to provide a space beneath a plurality of photovoltaic cells installed thereon (only a few photovoltaic modules are included, so the full extent of the support system can be seen);

FIG. 2 is a closer perspective view of the photovoltaic system of FIG. 1, taken from a lower angle to highlight a support structure configured to elevate the cables above the span;

FIGS. 3A and 3B are a top elevation views of the photovoltaic system of FIG. 1, illustrating non-limiting embodiments of arrangements of elongated photovoltaic modules for the plurality of photovoltaic cells;

FIG. 4 is a closer perspective view of the photovoltaic system of FIG. 1 than that of FIG. 2, illustrating angling of the photovoltaic modules on the plurality of cables;

FIG. 5 is a side profile view of the photovoltaic system of FIG. 1, showing angling of the photovoltaic modules and anchoring of the cable;

FIGS. 6A and 6B are bottom perspective views of the elongated photovoltaic modules of FIG. 1, illustrating non-limiting embodiments of mounting supports for the modules;

FIG. 7 is a side view of one of the elongated photovoltaic modules of FIG. 1, illustrating the mounting thereof to the cable, and electrical connections for the photovoltaic cells thereof;

FIG. 8 is a side cutaway view of another embodiment of one of the photovoltaic modules, showing an alternative mounting support therefore, and a light therein;

FIG. 9 is a side cutaway view of another embodiment of one of the photovoltaic modules, showing a construction configured to form a groove to support a light element therein; and

FIG. 10 is a top perspective view of an embodiment of one of the photovoltaic modules, showing the photovoltaic cells thereon.

### DETAILED DESCRIPTION OF THE ILLUSTRATED EMBODIMENT(S) OF THE INVENTION

The present application discloses photovoltaic cell system 10 with integrated solar cell photovoltaic technology. The illustrated embodiment is not intended to be limiting, and system 10 may have other configurations, constructions, and materials other than those mentioned below.

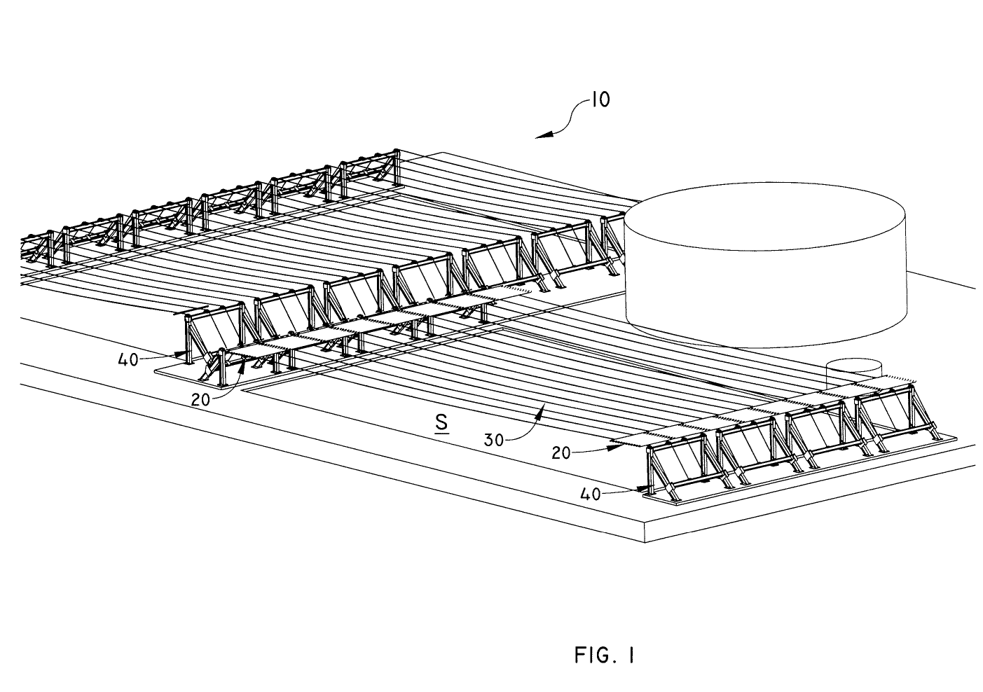

As shown in FIG. 1, system 10 provides a mechanism for arranging and supporting photovoltaic cell modules 20, described in greater detail below. Although system 10 may be utilized in any appropriate environment, system 10 may be particularly useful in arranging and supporting cell modules 20 across span S. Although the illustrated embodiment in FIG. 1 is assembled over the reservoirs of a water or sewage treatment plant, span S may include areas such as parking lots, building rooftops, fields, industrial facilities, roads, driveways, railroad tracks, canals, rivers, or so on. Any area that is outdoors and exposed to radiation from the sun, may be a suitable location for installation of system 10.

The basic components of system 10 are cell modules 20, a plurality of cables 30, and a pair of support structures 40. As FIG. 1 illustrates, the pair of support structures 40 lift cables 30 over span S, providing a space underneath. Although some cell modules 20 are shown in the figure, many are omitted for clarity of the Figure. In many embodiments cell modules 20 may be arranged throughout the entire length of cables 30, as is discussed in greater detail below. The length of span S may be of any appropriate length, but may be limited by the strength of cables 30 and cell modules 20. In an embodiment, cell modules 20 may be optimized to reduce their weight, so as to permit the installation of more cell modules 20 onto cables 30 across span S. In some non-limiting embodiments, the length of span S (across which cables 30 extend), may be between 15 and 200 feet long. In some embodiments, wherein span S is sufficiently long, additional support structures 40 may be placed at appropriate intervals to reduce strain on cables 30.

The space provided beneath cables 30 may be of any height, and may be customizable based on the environment in which system 10 is installed. For example, in the illustrated embodiment, wherein span S comprises water for a treatment plant, the spacing between the cables and the surface below may be only a small amount sufficient to keep cell modules 20 away from the foul water. In other installations, the spacing may be larger, so that a boat or barge may be placed in the water, in case access is needed for maintenance purposes. In installations wherein span S is a parking lot or other area where people may regularly be driving or walking, the spacing between cables 30 and the surface below may vary. Preferably in such installations, cables 30 should be spaced a sufficient amount to enable conventional motor vehicles (cars, pick-up trucks, etc.) to park beneath it without obstruction, and for people to walk to and from their vehicles comfortably. For example, cables 30 may be spaced at least 7 feet above the ground surface, and preferably 7.5 feet, 8 feet or 8.5 feet. Other heights may be used.

Cables 30 may be of any suitable construction or configuration. In various non-limiting embodiments, cables 30 may comprise wire, cord, rope, or chain. For example, cables 30 may be a solid elongated structure, may be braided or twisted, or may be formed from a plurality of links. Cables 30 may be constructed from any suitable material, including but not limited to metal, fiber, or synthetic materials. Cables 30 may essentially be formed from any suitable material capable of supporting cell modules 20 above span S.

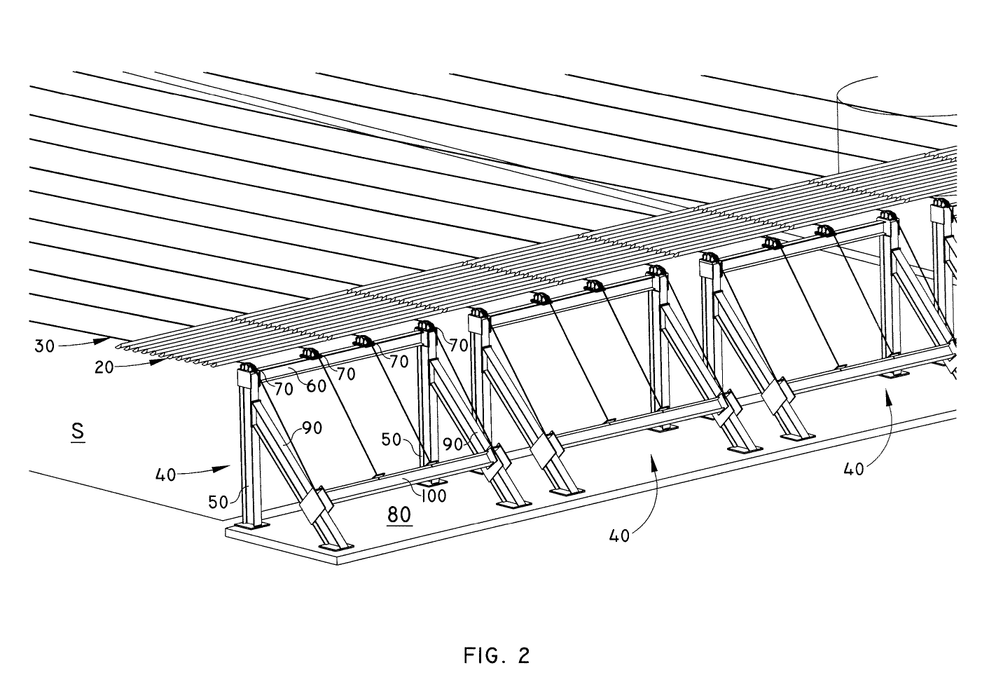

Turning to FIG. 2, the configuration of an embodiment of support structures 40 may be appreciated. The illustrated support structures are not intended to be limiting, and in some embodiments the support structures for cables 30 may be pre-existing structures, such as the roofs of adjacent buildings, adjacent high voltage towers, adjacent radio masts, or any other spaced structure. As shown in the illustrated embodiment, however, support structures 40 may be assembled specifically to raise cables 30 to a spaced height above span S. As shown, each of support structures 40 may comprise a pair of columns 50 connected at an upper end by cross beam 60. Each of columns 50 are shown as substantially comprising a single girder, having an I-beam configuration. In other embodiments, columns 50 may be comprised of multiple elements, and the illustrated construction is not intended to be limiting. Cables 30 may be mounted to or pass over cross beam 60, which is also shown as substantially comprising a single girder, but in other embodiments may comprise multiple elements. In an embodiment, the height that columns 50 lift cross beam 60 may define the general height of cables 30 above span S. As described above, this may be any suitable height, including but not limited to approximately 7-8 feet, such that a person may comfortably traverse the underside of cables 30 across span S.

As shown in the illustrated embodiment, cross beam 60 may have cable guides 70 mounted thereon, which may receive the lengths of cables 30 from across span S, and may redirect cables 30 so that they may be secured or anchored. In some embodiments, cable guides 70 may apply a force to cables 30, and may be used to tighten cables 30 to prevent sagging. In some embodiments, system 10 may further provide a cable tightener to adjust a tension on one or more of the plurality of cables 30. In an embodiment the cable tightener may be located at support structure 40. In some embodiments, the cable tightener may anchor cables 30, and may, for example, comprise a winch configured to receive an end of at least one cable 30.

Columns 50 may be mounted into footing 80, which may comprise concrete or other dense material to provide a sturdy and secure foundation for support structures 40. In an embodiment, footing 80 may include one or more anchors extending into the Earth to provide a more stable foundation, and prevent movement of support structures 40 with respect to span S. Examples of an anchor may include, but are not limited to, drives piles, caissons, helical piles/screws, etc. To prevent tipping or other failure of columns 50, support structures 40 may further include one or more braces 90 to support columns 50. Braces 90 may also be mounted into footing 80, and in an embodiment may extend at an angle to intersect columns 50, distributing the forces (such as tension forces) resulting from the pull of cables 30 on cross beam 60. As shown in the illustrated embodiment, second cross beam 100 may extend between braces 90, on which cables 30 may be anchored.

As seen in the Figure, in an embodiment, a plurality of support structures 40 may be provided wherein each are associated with a subset of the plurality of cables 30. As shown, each support structure 40 may support four of cables 30. In other embodiments, each support structure 40 may support less cables 30 (i.e. two cables 30) or more cables 30 (i.e. if the separate support structures 40 of FIG. 2 were connected). As shown, in some embodiments, support structures 40 may share a common footing 80.

Support structures 40 may be of any suitable construction or configuration, including but not limited to metals such as iron, steel, or aluminum, natural formations such as rocks, trees, or soil, or building materials such as brick, concrete, or processed wood. As stated above, any structure that is capable of supporting cables 30, raising them to the desired spaced height above span S, and preventing them from failing under the weight of cell modules 20 may be utilized to support or anchor cables 30.

For example, the vertical columns/support for vertically supporting cables 30 and the cable end anchor(s) to which cables 30 are connected to maintain tension in cables 30 may be provided as separate structures, rather than sharing a common footing 80 as illustrated. In such an approach, cable 30 and anchors would typically use a secure ground anchor or anchors (examples provided above) to resist the pulling/tension of cables 30.

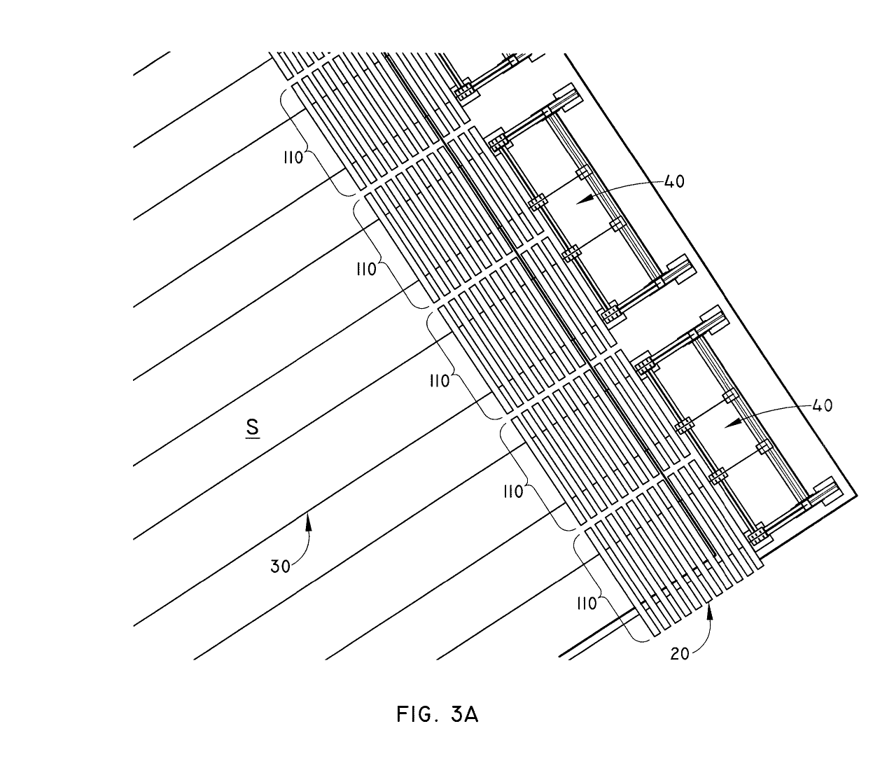

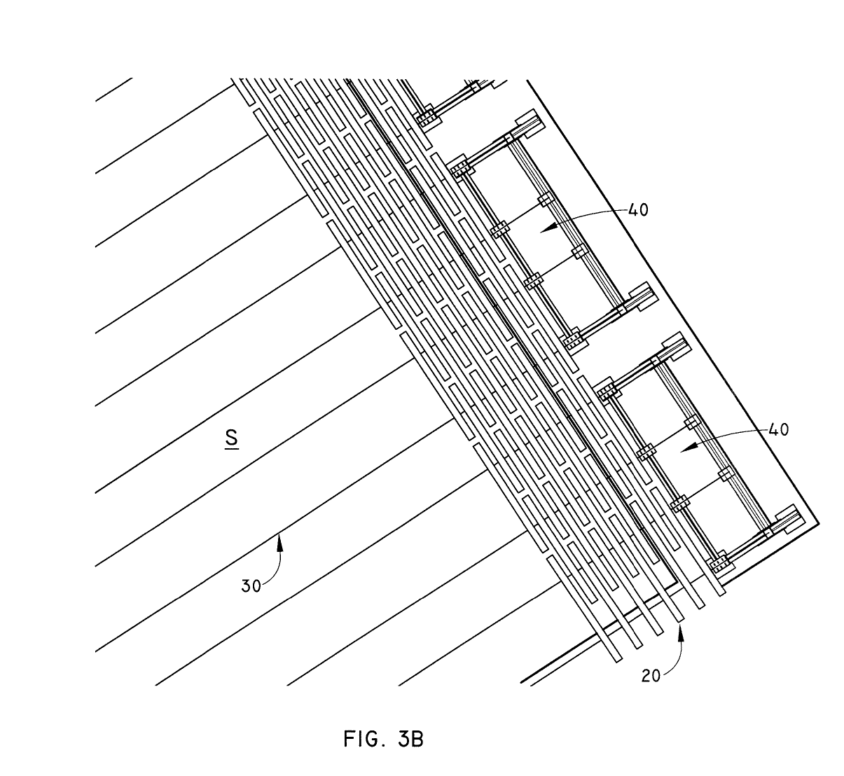

Illustrated in FIGS. 3A and 3B are non-limiting examples of how cell modules 20 may be arranged on or mounted to cables 30, the mechanics of which are described in greater detail below. Seen in FIG. 3A is a top view of the arrangement of cell modules 20 seen in FIGS. 1 and 2. As shown, each cell module 20 is associated with and supported by two of cables 30. As shown, associated pairs of cables 30 may form columns of cell modules 20, hereinafter referred to as strings 110. In some non-limiting embodiments, each string 110 of cell modules 20 may be electrically connected to one another. The spacing of cables 30 from one another may be determined by the size of cell modules 20. In some embodiments, cell modules 30 may be substantial in length, but not in width. For example, in some exemplary embodiments, each cell module 20 may be approximately 18 feet long, but only approximately one foot wide. In some embodiments, cell modules may be associated with more than two cables 30, to provide additional support for cell modules 20.

In some embodiments, cell modules 20 along and between strings 110 may be spaced from one another. In some embodiments, the spacing is achieved by the mounting of cell modules 20 on cables 30. In other embodiments, the spacing may be achieved by spacers placed between cell modules 20 to help separate them, which may reduce overall weight at any point on cable 30, or may allow some sunlight through between cell modules 20. Such a spaced apart relation also permits airflow between cell modules 20. That is, because cell modules 20 are spaced apart from one another, wind blowing over cell modules 20 can flow through the spaces therebetween. This minimizes any lift or downward force generated by airflow over the plurality of cell modules 20, as may occur with sheets of photovoltaic cells forming a solid canopy structure. Likewise, snow or water will fall through the open spaces, thus eliminating or minimizing the accumulation of snow and ice (or other precipitation, such as hail) in cold conditions. The spacing between cell modules 20 may be of any size, and in an embodiment, may be at least four inches, so as to minimize the potential for snow buildup, or to optimize airflow between cell modules 20.

Although the spaced apart relation of cell modules 20 may minimize lift or downward forces on cell modules 20, in some embodiments strings 110 of cell modules 20 may still be prone to twisting or be subject to other unwanted forces. In some embodiments, such twisting may be further minimized by providing lateral cross braces connecting the pluralities of cables 30 at one or more spaced intervals, such that all strings 110 of cell modules 20 are interconnected at one or more places. The lateral cross braces may additionally provide lift for the pluralities of cables 30, and may be positioned to reduce sagging of cables 30 under the weight of cell modules 20. Such lateral cross braces may comprise additional cables that extend across the plurality of cables 30. In some embodiments, the lateral cross braces may be anchored to additional support structures 40 oriented perpendicular to support structures 40 for cables 30. In other embodiments, the lateral cross braces may be anchored only to cables 30 themselves, which may serve to more evenly distribute the weight of cell modules 20. In some embodiments, the lateral cross braces may be interwoven alternatively above or below adjacent cables 30.

FIG. 3B shows an alternative arrangement for cell modules 20, which may reduce or eliminate twisting or the need for lateral cross braces by providing greater interconnection across cables 30. As shown, instead of forming strings 110, cell modules 20 may be staggered across adjacent cables 30, creating a stretcher-bond bricklayer-like appearance for cell modules 20, as shown. Such a staggered configuration may more evenly distribute the weight of cell modules 20 without the need for a dedicated lateral cross brace. In some embodiments, cell modules 20 may generally be arranged in strings 110; however, they may also intermittently be arranged in staggered association with adjacent cables 30, thus indirectly associating a larger number of adjacent cables 30 with one another.

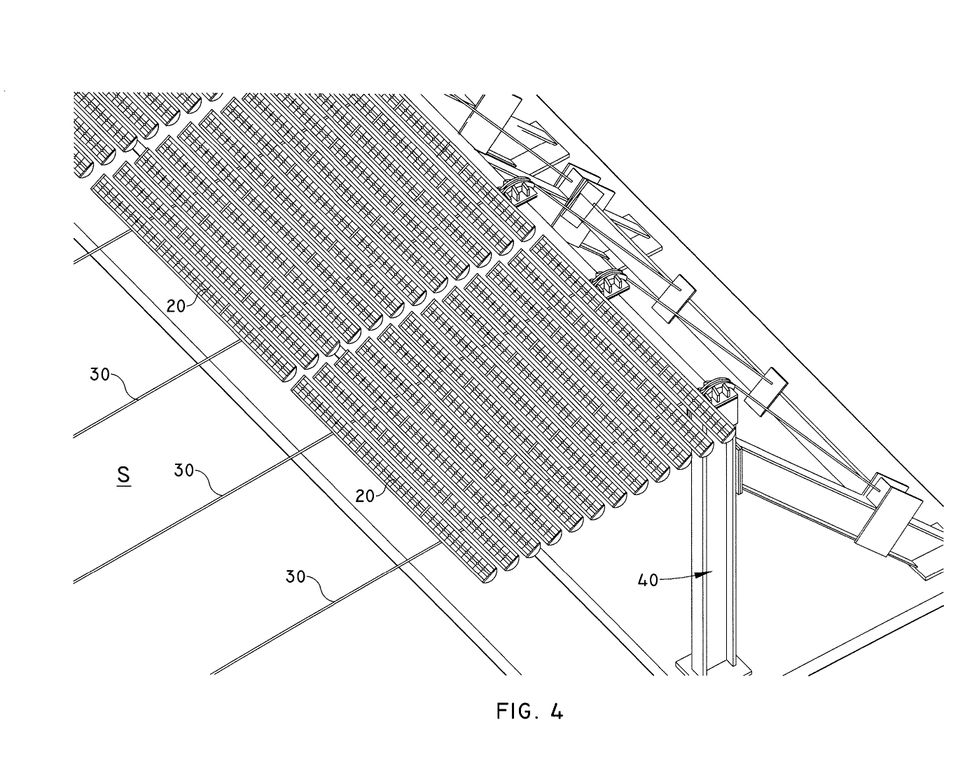

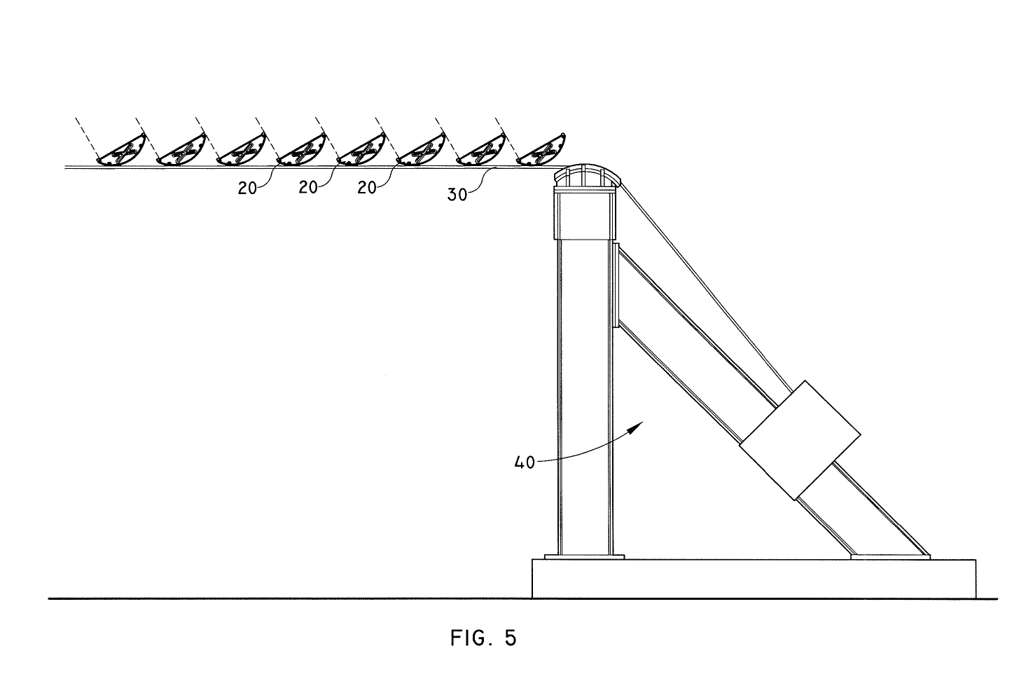

As is shown in FIGS. 4 and 5, in some embodiments, each of cell modules 20 may be angled with respect to the direction of cables 30 along span S. Although the connection between cables 30 and cell modules 20 are described in greater detail below, it may be appreciated that depending on the location of system 10, the sun may rise at a different portion of the sky, and for parts of the year may track across an acute angle formed with the horizon. An ideal angle for cell modules 20 to receive light from the sun may change according to the time of year, the location of the system, precision of the Earth, or so on. For these or other reasons, angling of cell modules 20 may permit a greater amount of light to fall on the photovoltaics of cell modules 20, allowing the generation of greater amounts of electricity. In some embodiments, cell modules 20 may contain mechanical tracking devices configured to allow the angle of cell module 20 as against cables 30 to change as the sun moves across the sky, to further optimize light collection by cell module 20.

As is illustrated in greater detail in FIG. 5, in some embodiments, the angles that cell modules 20 form with respect to cables 30 may be optimized such that the most common path of the sun across the sky creates shadows predominantly in the spacing between cell modules 20 on cables 30, and not on the photovoltaics of cell modules 20. Such an optimization may comprise adjusting the shape of cell modules 20, the spacing of cell modules 20 on cables 30, or so on. In some embodiments, the angles that cell modules 20 are mounted at with respect to cables 30 may vary, such that different cell modules 20 are optimized to receive light from the sun from different times during the day. In some embodiments, sagging of cables 30 may be accounted for in the angles at which cell modules 20 are mounted.

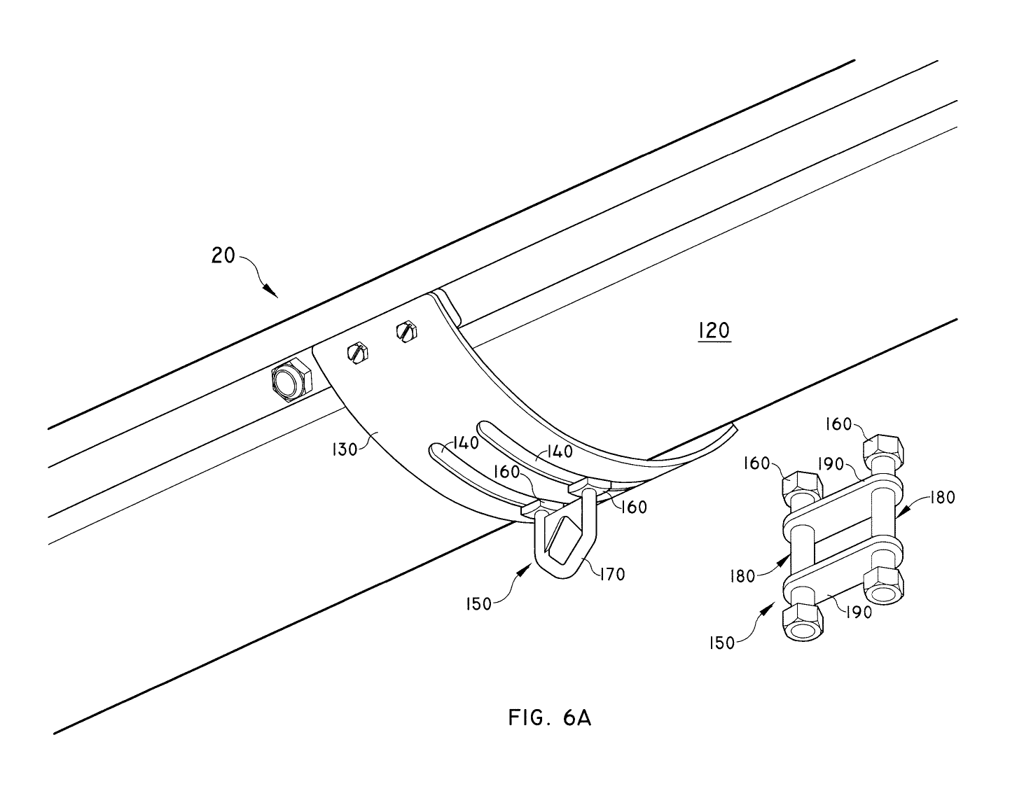

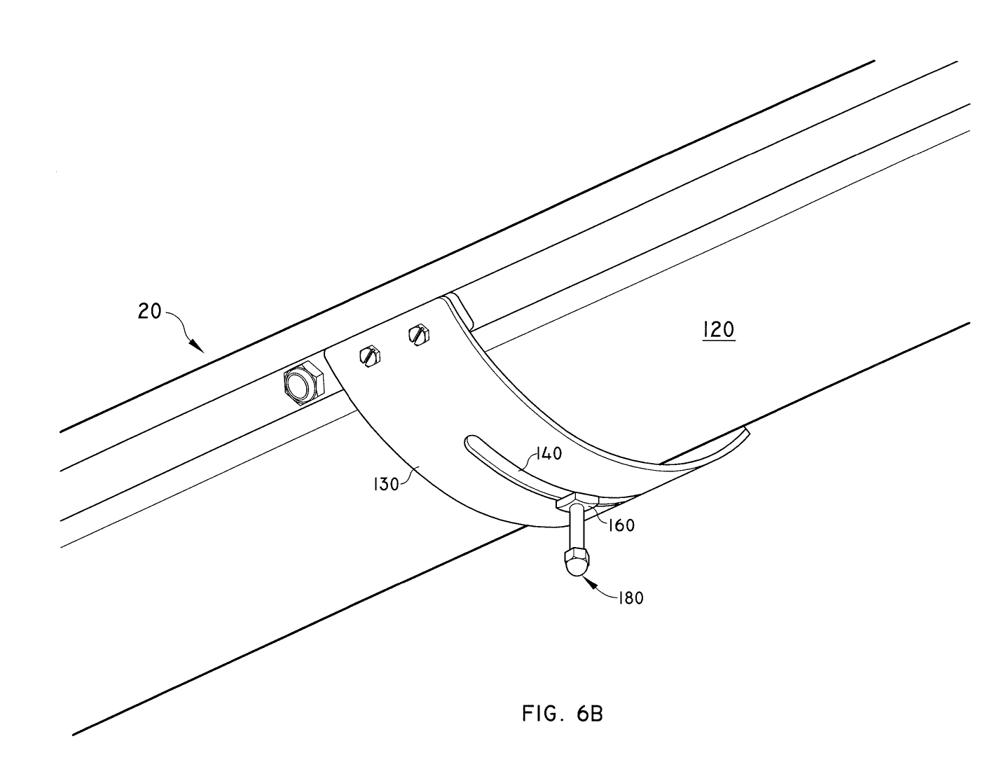

In FIGS. 6A and 6B, non-limiting embodiments of the mounting of cell modules 20 to cables 30 may be appreciated. These embodiments are exemplary, and may vary across different embodiments of system 10, such as differing depending on the configuration of cable 30. Shown in FIG. 6A is the underside of an embodiment of cell module 20. As shown, cell module 20 includes base member 120. In the illustrated embodiment, base member 120 may be a convex arcuate surface. In some embodiments, the mounting for cables 30 may be built directly into base member 120. For example, base member 120 may include a plurality of associated perforations along the arcuate shape, configured to receive cable 30 through any two of the perforations. In the illustrated embodiment of FIGS. 6A, however, mounting bracket 130 attached to base member 120 is provided, which may be attached to cables 30 in a variety of ways. As shown, bracket 130 comprises two apertures 140 formed as elongated slots therein, through which may be installed cable engaging member 150. Fasteners 160 on cable engaging member 150 may allow cable engaging member 150 to be tightened onto different areas of apertures 140, allowing greater adjustability of the angle formed between cable 30 and mounting bracket 130 (and thus, cell module 20). Many cable engaging members 150 are known in the art, such as but not limited to U-shaped bolt 170, seen installed on bracket 130 in FIG. 6A. In other embodiments, other generally U-shaped brackets may also be installed around cable 30 to secure cable 30 to bracket 130 or base member 120, and may be fastened by other means such as welding, adhesive, screws, or so on. Another non-limiting example of cable engaging member 150 may include the assembly of two bolts 180 with one or more cross-members 190, shown alongside U-shaped bolt 170, which may clamp onto cable 30, and secure it to either another cross member 180 or to bracket 130 or base member 120.

Where cables 30 lack apertures therein, any body that may create an enclosure to secure cables 30 to brackets 130 and/or base members 120 may be utilized. Other examples of such cable engaging members 150 may include cable ties (i.e. zip ties), twist ties (i.e. bent wire), straps, or so on. In some embodiments, cable engaging members 150 may comprise knotted thread, twine, or rope. In some embodiments, cable engaging members 150 may be threaded through apertures 140, creating a loop through which cables 30 may be fed so that cables 30 are generally perpendicular to a direction of elongation for cell modules 20.

In an alternative embodiment shown in FIG. 6B, bracket 130 of cell modules 20 may comprise a single aperture 140, through which may be threaded a single bolt 180. Such a bolt 180 may be acceptable to mount cell modules 20 to cables 30 where, for example, cables 30 comprise apertures therein. For example, where cables 30 are chains, bolt 180 may be passed through an aperture of a link in the chain of cable 30, and secured by fasteners 160. Again, the mechanism for mounting cell module 20 to cables 30 may vary depending on the constituent makeup of cables 30. In some embodiments, an appropriate adhesive may be utilized to bond cables 30 to cell module 20. For example, where cables 30 are comprised of metal, in some embodiments cell modules 20 may be welded directly to cables 30. In such embodiments, a generally curved shape of base member 120 or bracket 130 may allow the varying position of the welding to adjust the angle that the photovoltaics of cell module 20 forms with cables 30. In other embodiments, such as where cables 30 comprise a fabric material such as rope, a cable engaging member may be utilized such as pins, needles, spikes, or other similar bodies that may push through a portion of cables 30 to secure cell modules 20 onto cables 30. Other constructions or configurations may be used, and the listed examples are not intended to be limiting.

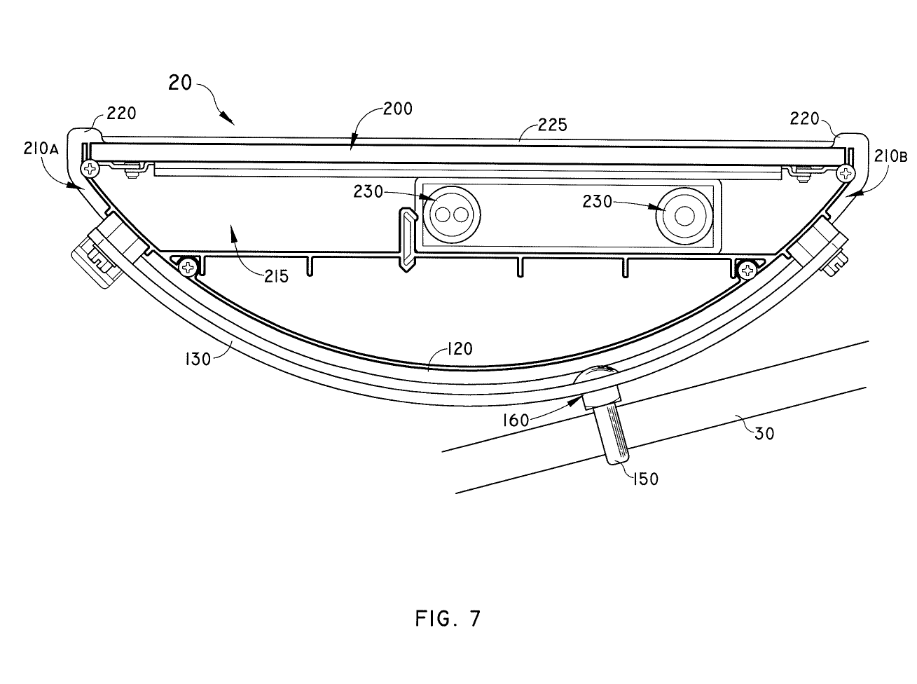

Turning to FIG. 7, a side view of an embodiment of cell module 20 is depicted as mounted to cable 30. As shown, bracket 130 is mounted to base member 120 of cell module 20, spaced so that a portion of cable engaging member 150 may be secured by fasteners 160. In some embodiments, once cable engaging member 150 is installed onto a selected position of bracket 130, their combination may then be installed onto base member 120 of cell module 20. Also seen from the side view depicted is photovoltaic cell assembly 200, containing the active photovoltaics of cell module 20, installed onto base member 120. The composition of photovoltaic cell assembly 200 is described in greater detail below. In the illustrated embodiment, base member 120 comprises a generally arcuate body defined by first and second extensions 210a and 210b outwardly extending from a common point (i.e. a midpoint), whereby photovoltaic cell assembly 200 is retained or otherwise supported by the endpoints of base member 120 at the ends of first and second extensions 210a-b. It may be appreciated that the ends of the first and second extensions 210a and 210b of the elongated base member 120 may generally define an elongated support plane that extends therebetween. When photovoltaic cell assembly 200 is retained or otherwise supported by the ends, photovoltaic cell assembly 200 may generally extend along the elongated support plane. It may be appreciated that “extending generally along the elongated support plane,” implies that at least a portion of photovoltaic cell assembly 200 resides along the plane, and is elongated with the elongated support plane. To be clear, in various embodiments portions of photovoltaic cell assembly 200 may be outside the elongated support plane, or may be angled with respect to the elongated support plane.

It may be appreciated that while in some embodiments first extension 210a may be integrally coupled to or formed with second extension 210b, in other embodiments, first and second extensions 210a-b may be formed separately and subsequently coupled or otherwise assembled together, as described in greater detail below. It may be also be appreciated that the shape of first and second extensions 210a-b as they extend from the common point towards photovoltaic cell assembly 200 defines space 215 between base member 120 and photovoltaic cell assembly 200. It may be appreciated that space 215 may define a volume between base member 120 and photovoltaic cell assembly 200. Space 215 may therefore be a region generally bounded by base member 120 and photovoltaic cell assembly 200, and may in some embodiments be sufficiently voluminous so as to facilitate containing elements of cell module 20 therein, as described in greater detail below. In some embodiments, space 215 may be bounded by the elongated support plane, while in other embodiments photovoltaic cell assembly 200 may be shaped so as to meet the ends of base member 120, such that a portion of the elongated support plane extends within space 215. Although in some embodiments space 215 may be generally or completely enclosed, in other embodiments, gaps between elements of photovoltaic cell assembly 200 and/or base member 120 (i.e. between first and second extensions 210a-b), and/or apertures within photovoltaic cell assembly 200 and/or elements of base member 120 (i.e. in first or second extensions 210a-b), may provide external access to space 215.

As shown in the illustrated embodiment, first and second extensions 210a-b may comprise or be connected to associated inwardly extending lips 220a-b, which may prevent outward removal of photovoltaic cell assembly 200. In an embodiment, photovoltaic cell assembly 200 may be further supported from the interior of base member 120 such that photovoltaic cell assembly 200 does not slip away from lips 220a-b. In some embodiments, lips 220a-b and another portion associated with base member 120 may form slots extending in the direction of elongation for cell modules 20, so that one or more photovoltaic cell assemblies 200 may slide into to install photovoltaic cell assemblies 200 into base member 120. In other embodiments, photovoltaic cell assemblies 200 may be mounted to the ends of first and second extensions 210a-b, instead of being retained within them. For example, lips 220a-b may form a ledge to support photovoltaic cell assemblies 200. In some embodiments the mounting of photovoltaic cell assemblies 200 to base member 120 may be with screws, bolts, adhesive, or any other appropriate fastener. In an embodiment, multiple mechanisms to fasten photovoltaic cell assemblies 200 into base member 120 may be utilized.

Photovoltaic cell assemblies 200 may be of any suitable construction configured to support active photovoltaics for cell modules 20. In an embodiment, photovoltaic cell assembly 200 may comprise a rigid backing member or substrate, which may be of any suitable construction, including but not limited to plastic or foam. In various embodiments, the backing member may comprise polycarbonate, fiberglass, glass, polycarbonate, and/or aluminum laminate (two thin layers of aluminum laminated together using a plastic waffle-like structure). In some embodiments, the backing member may be in a honeycomb or other porous configuration to reduce the weight of cell modules 20. In some embodiments, the backing member may comprise or be surrounded by layers or a rigid material, such as in the aforementioned aluminum laminate, or any other sturdy material, to increase the structural stability of photovoltaic cell assembly 200, while maintaining a relatively light weight. The active photovoltaics of cell assembly 200 may reside against the backing member or the rigid material facing away from base member 120, to receive light shining onto the active photovoltaics for conversion into electricity. In an embodiment, cell assembly 200 may comprise transparent protective material 225 placed over the active photovoltaics on the side facing away from base member 120, so as to prevent damage to the active photovoltaics. In some embodiments, the backing member may be a thicker transparent protective material 225, and the active photovoltaics may be mounted to the underside of transparent protective material 225, to increase protection from the exterior environment. While in some embodiments lips 220 may also be configured to retain both photovoltaic cell assembly 200 and transparent protective material 225, in other embodiments, such as that shown, transparent protective material 225 may be adhered directly to photovoltaic cell assembly 200. The active photovoltaics and transparent protective material 225 are discussed in greater detail below.

In an embodiment, photovoltaic cell assemblies 200 may be bonded using any suitable adhesive, including but not limited to EVA or other clear plastic sheets in a vacuum lamination process. In an embodiment, if the adhesive is between the light collecting portion of the active photovoltaics and a transparent body such as transparent protective material 225, the adhesive is preferably light transmissive, so as to enable the maximum amount of light transmittance to occur onto photovoltaic cell assembly 200. In an embodiment, a backing of photovoltaic cell assembly 200 may be larger than the active photovoltaics so that bonding may be at the edge of the backing, thus avoiding any adhesive between the active photovoltaics and the interior surface of base member 120.

Further shown in the side view of FIG. 7 are electrical terminals 230 for the one or more photovoltaic cell assemblies 200 of cell module 20. The manner in which photovoltaic cell assemblies 200 function, by receiving solar radiation and converting the solar radiation to electricity, is known and need not be detailed herein. In an embodiment, both positive and negative terminals 230 may be provided on the same side of elongation for cell module 20, which may simplify the connection of electrical cables to electrically connect cell modules 20 associated with the same cables 30 on the same string 110. In some embodiments, the positive and negative terminals 230 may be positioned on opposing sides of elongation for cell module 20, which may simplify the connection of electrical cables to electrically connect cell modules 20 of the same row on different strings 110. In some embodiments, cables 30 may be electrically conductive, such as where they are formed from metal, and thus may serve to electrically connect cell modules 20 of string 110 in parallel. For example, where two cables 30 are associated with string 110, one cable 30 may be associated with the positive terminal 230 for each cell module 20, while the second cable 30 may be associated with the negative terminal 230 for each cell module 20. In such embodiments, the electrical connection between the respective terminals 230 and the electrically conductive cables 30 may be formed through cable engaging member 150. The manner of establishing electrical connections may vary. For example, instead of wiring, integrated connectors may be built into the various components to facilitate such connections during assembly. Thus, the application is not limited to the examples mentioned herein.

Other electrical connections between cell modules 20 are also possible. Connecting all cell modules 20 in series maximizes the potential or voltage, while connecting cell modules 20 in parallel maximizes current output. In some embodiments, it may be desirable to combine both parallel and serial connected cell modules 20 to provide desired levels of both voltage and current. Various combinations of serial and parallel connected cell modules 20 may be used, and this description is not intended to be limiting.

In many embodiments, a power output may be established for string 110 of cell modules 20, or for all cell modules 20 in system 10, to output the electricity converted in each of cell modules 20. In various embodiments, the power output may be located on or near one or more of structural supports 40. This power output may be any suitable device for collecting the electricity and distributing the same to a larger network or grid. For example, the power output may be an inverter, which is a standard piece of equipment used to convert the DC electrical signal generated by photovoltaic elements in cell modules 20 into an AC signal that is compatible for use with standard power grids. As another alternative, the power output could simply output a DC signal, whereby a common inverter may receive DC signals from a plurality of systems 10, and convert them to an AC signal.

The power output may couple to one or more energy storage devices, such as a rechargeable battery, so that the energy generated may be stored for later use. This is particularly beneficial because the photovoltaic power generation does not function at night, and may be interrupted for long or short periods during the day. The use of an energy storage device allows for continued output of electricity, even when demand for the electricity does not coincide with the power generation of the photovoltaic cells. The electricity generated by the photovoltaic cells may be used by adjacent buildings or other devices, as is discussed in greater detail below, or may be sold to the local power grid to generate revenue.

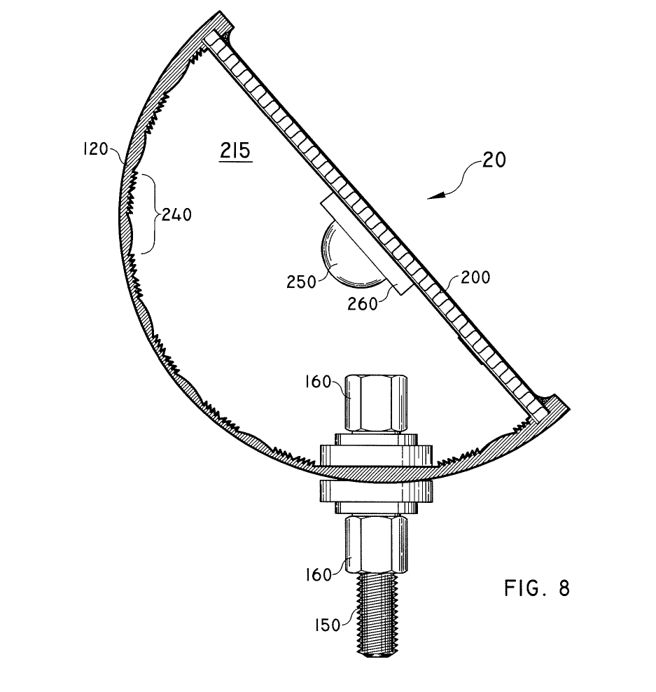

Each component of cell modules 20 supporting photovoltaic cell assembly 200 may be formed of any suitable material, including but not limited to aluminum, stainless steel, composite materials, plastics, polymers, other metals, or so on. Further to reducing the weight of cell modules 20, and the forces that are placed on cables 30, lightweight materials are preferable. In an embodiment, base member 120 may be constructed from polycarbonate, PVC, fiberglass, and/or acrylic. In an embodiment, base member 120 may be formed from a half round tube having a flat top surface for mounting photovoltaic cell assemblies 200. In the illustrated embodiment of a half-round tube configuration for base member 120, the diameter of the tube may be selected to match the width of photovoltaic cell assembly 200; however other widths may be selected. As shown in FIG. 8, which depicts another embodiment of cell module 20, the half round tube may be made in a continuous casting process, and/or may have a profile departing from a simple half circle. As an example, the shape can be generally elliptical, or polygonal. To be clear, in some embodiments, base member 120 may generally conform to other tube shapes, including but not limited to a generally half circular shape, a generally half elliptical shape, or so on. Likewise, in some embodiments, the shape of the tube configuration of base member 120 might be polygonal, as opposed to rounded, in configuration. For example, as described above, base member 120 might form a triangular prism shape when combined with photovoltaic cell assembly 200, or may contain additional facets, such that the tube configuration of base member 120 forms a rectangular, pentagonal, hexagonal, or other multi-faceted polygonal shape when combined with photovoltaic cell assemblies 200. Additionally, in some embodiments, base member 120 may contain both rounded and polygonal portions. The walls of base member 120 may be of any suitable thickness, and in an embodiment base member 120 may contain structural embellishments 240, as shown, which may strengthen base member 120.

In the embodiment of FIG. 8, structural embellishments 240 of base member 120 may be configured to amplify light emitted by one or more light sources 250, and thus may act as a plurality of lenses. In such an embodiment, the material of base member 120 may be at least partially transparent, such as if, for example, base member 120 comprises optical grade polycarbonate. In an embodiment, a series of light sources 250 may be placed along the length of cell module 120, so as to illuminate the area below base member 120. In various embodiments, light sources 250 may be attached to the underside of photovoltaic cell assembly 200, or may be attached to base member 120. In an embodiment, light sources 250 may comprise light emitting diodes (LEDs), which may be soldered directly to a printed circuit board 260 extending along the length of cell module 20, and may be at least partially powered directly or indirectly (i.e. through a storage battery) by photovoltaic cell assemblies 200. In other embodiments, light sources 250 may comprise other types of lighting, including but not limited to incandescent, florescent, or metal halide. The use of light sources 250 in cell modules 20 may be useful when system 10 is installed in an area prone to travel, or where lighting is needed, such as if system 10 is installed over a parking lot. In some embodiments, the backing of photovoltaic cell assembly 200 may have an adherent quality, which may allow adhesion of light source 250, printable circuit board 260 and/or other elements of cell module 20.

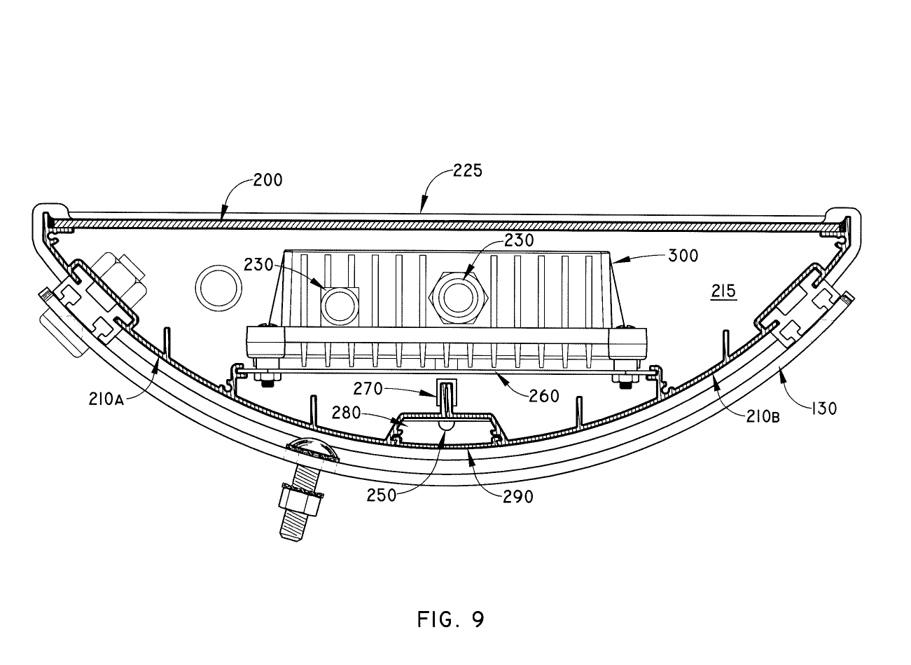

As noted above, in some embodiments, first and second extensions 210a-b may be formed as separate bodies, which may be subsequently joined together to form base member 120. An example of such an embodiment is shown in FIG. 9, where first extension 210a and second extension 210b meet together at a common meeting point. In the illustrated embodiment, clip 270 secures the meeting edges of first and second extensions 210a-b together. In other embodiments, any other securing mechanism may be utilized, including but not limited to fasteners, adhesives, crimping, folding onto one another, or so on. As shown in the illustrated embodiment of FIG. 9, in some embodiments, first and second extensions 210a-b may be shaped to form channel 280 around their common meeting point, along the outside of base member 120. In various embodiments, light source 250 may be positioned in channel 280, such that light source 250 is supported by base element 120. In an embodiment, light source 250 may comprise one or more light elements that extend along channel 280 (i.e. as a strip of lights, or as an elongated light tube). In an embodiment, cover 290 may at least partially enclose channel 280, and in some embodiments may generally follow a contour shape defined by base member 120. In an embodiment containing light source 250 in channel 280, cover 290 may be transparent such that light source 250 may emit light therethrough.

As further shown in FIG. 9, in some embodiments, first and second extensions 210a-b may be configured to support printed circuit board 260 within space 215. Additionally, in various embodiments, other components may be mounted inside base member 120 (i.e. in space 215), such as on printed circuit board 260, to the interior of first and second extensions 210a-b, or to the backing of photovoltaic cell assembly 200. For example, in various embodiments sensors, power conversion devices, or other electronics may be installed, which may also be at least partially powered directly or indirectly (i.e. through a storage battery) by photovoltaic cell assemblies 200. As shown in the illustrated embodiment, power inverter 300 is installed in space 215, which may be electrically coupled to light sources 250. It may be appreciated that in embodiments where light sources 250 are LEDs, light sources 250 would utilize DC power. Accordingly, power inverter 300 may facilitate converting AC power (i.e. from the grid) to DC power to power light sources 250 or other electronic systems at cell module 20 once photovoltaic cell assembly 200 is no longer producing DC power. In some embodiments where batteries or other power storage is located in space 215 or otherwise are associated with cell module 20, power inverter 300 might be utilized solely for conversion of the DC power generated by photovoltaic cell assembly 200 to AC power for supplying the electrical grid. Depending on light sources 250 used in such embodiments of cell module 20, or other electrical systems utilized in cell module 20, various components such as but not limited to resistors, capacitors, and integrated circuits may be mounted to printed circuit board 260 to supply appropriate power to light sources 250 or those other electrical systems. In some embodiments, printed circuit board 260 may carry the electrical current generated by photovoltaic cell assemblies 200, and may direct the current to terminals 230. In some embodiments, wires and other electronic connections associated with cell module 20 (i e running to and from printed circuit board 260) may be housed within space 215.

In some embodiments, base member 120 may further house additional elements (i.e. at least partially in space 215, or otherwise coupled to base member 120), such as but not limited to motion detectors, cameras, displays, or RFID tag readers. In an embodiment, such as when base member 120 includes a motion detector comprising a passive infrared detector, cell module 120 may detect when a person or vehicle is near system 10, and may perform some response function, such as turning on light sources 250, displaying content on the displays, recording video on the cameras, or so on. For example, content displayed on the displays may serve as an electronic billboard. In such an embodiment, some of base members 120 in system 10 could be fitted with a long character or graphic displays to provide information or advertising. For example, where system 10 is installed over a parking lot, the graphic displays and motion detectors could be used to track empty parking spaces, and indicate to drivers where a free space is available for the driver to park. In embodiments containing cameras, the cameras may be used to provide security, or identify vehicles parked under cell modules 20. In embodiments comprising an RFID tag reader, the reader may be used to read a tag mounted on cars parked below cell modules 20, and may transmit this information to enable billing (such as parking fees, for example).

In an embodiment, circuitry can be added to system 10 to monitor the health of cell modules 20, such as by measuring electric output and solar input (i.e. by using a photo detector). In an embodiment, the circuitry may include a temperature sensor to help calibrate power measurements, and warn of environmental conditions, such as the threat of icing.

In some embodiments, information about cell modules 20, such as from the sensors, may be transmitted to a central data collection point. In some embodiments, this transmission may be wireless, including but not limited to via cellular, 802.11 WiFi, Zigbee®, or Bluetooth® transmission standards. In some embodiments, the transmission may be through wires, such as through dedicated data cables, or through power cables connecting cell modules 20 (i.e. through transmission standards such as HomePlug®, X10, or other power line communications). In an embodiment, information collected from cell modules 20 may be utilized to track the utilization of parking spaces, alert authorities to the presence of intruders, or so on. In an embodiment, cell modules 20 may contain controllers that may be controlled via the wired or wireless transmission standards described above, for example. Such controllers may receive external commands, which may perform a variety of functions, including controlling light sources 250, the displays, the cameras, or so on.

As noted above, in some embodiments, it may be desirable to convert the direct current (DC) output of photovoltaic cell assemblies 200 into alternating current (AC) compatible with utility grids. Such conversion is typically performed by an inverter such as power inverter 300, which in some embodiments may be mounted onto or at least partially inside base member 120 (i.e. extending into space 215). In an embodiment, power inverter 300 may be a separate assembly inside base member 120, or may be assembled into printed circuit board 260. In embodiments where power inverter 300 is incorporated into cell modules 20, light sources 250 may be controlled by the same wire used for AC output of cell module 20. Likewise, light sources 250 may be controlled by the same networked controller as is used for power inverter 300, which may reduce circuitry required in each cell module 20, by having the same processor handle control functions for both the inverter and light sources 250. The same controller may additionally be used to control the sensors or other electronic components located in cell module 20. In some embodiments, other energy sensing or harnessing technologies may additionally be used in cell modules 20, such as wind impellers for further electricity generation.

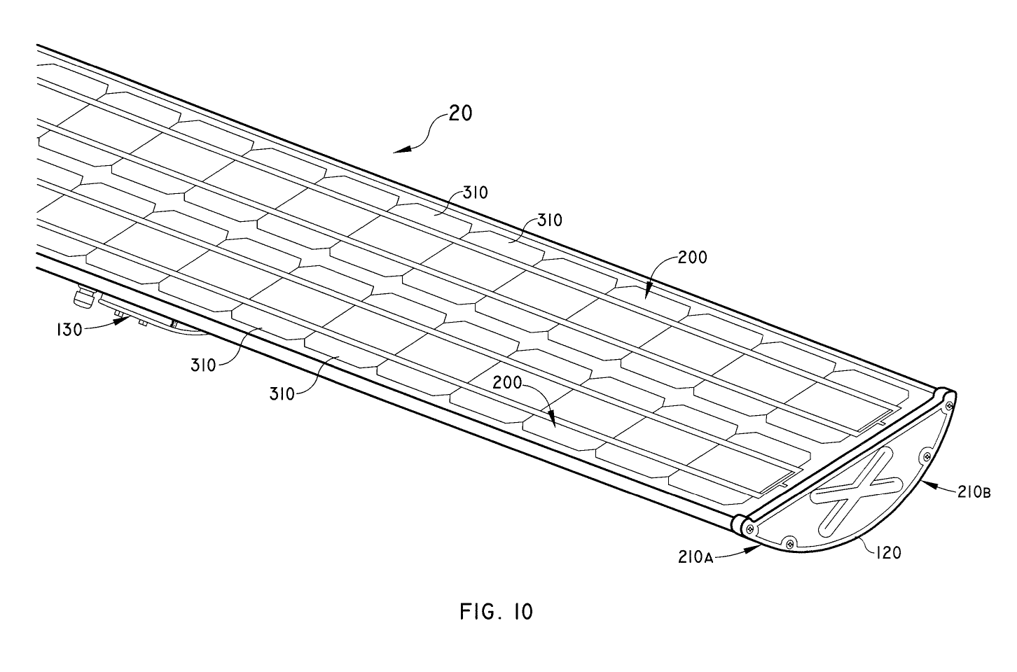

Turning now to FIG. 10, an embodiment of cell module 20 is seen from an elevated perspective view, such that active photovoltaics 310 on photovoltaic cell assemblies 200 are shown. It may be appreciated that in various embodiments cell module 20 is greatly elongated. For example, in some embodiments cell module 20 has a general ratio of height to length that is approximately greater than 1:3, including for example, approximately 1:5, approximately 1:7, approximately 1:10, approximately 1:15, or so on. As seen, the illustrated embodiment of cell module 20 comprises numerous active photovoltaics 310 arranged in an array. In some embodiments, active photovoltaics 310 may be associated with different photovoltaic cell assemblies 200, which may in combination be assembled onto base member 120. In the illustrated embodiment, base member 120 has associated therewith two photovoltaic cell assemblies 200, each having a strip of active photovoltaics 310 thereon, such that cell module 20 contains an array of active photovoltaics 310 that is two active photovoltaics 310 wide, and significantly longer in active photovoltaics 310 in length. The number of active photovoltaics 310 on each photovoltaic cell assembly 200 and in each cell module 20 may vary, and the size of base member 120 and/or the size of photovoltaic cell assemblies 200 may increase to compensate. As described above, photovoltaic cell assemblies 200 and transparent protective material 225 may be of any construction or configuration. In some embodiments, however, transparent protective material 225 on the outer external surface of photovoltaic cell assembly 200 may be of a non-glass configuration, such as that disclosed in U.S. Patent Application Publication No. 2009/0272436, incorporated herein by reference. Although conventional glasses may be used as the transparent protective materials 225 in some embodiments, it may be appreciated that a non-glass configuration may reduce the weight of cell modules 20, allowing more cell modules 20 to be arranged on cables 30. In an embodiment, photovoltaic cell assemblies 200 may comprise crystalline silicon or thin film cells mounted to the backing member between first and second extensions 210a-b.

In an embodiment, transparent protective material 225 may be a top layer of laminate over photovoltaic cell assembly 200. In an embodiment, transparent protective material 225 can be a coating material such as DuPontTM Tefzel® or other fluoropolymer, which may provide a suitable vapor barrier and provide weathering resistance. This material may be coated directly onto photovoltaic cell assemblies 200, and cured in place over active photovoltaics 310 and backing member. This not only weighs less than glass and may be thinner than glass, but may also avoid the need for an adhesive layer between it and active photovoltaics 310, which may detract from light transmission. In some embodiments, the backing member may be comprised of multiple bodies that are joined together, either through adhesion, fasteners, interlocking, or any other mechanism. In an embodiment, photovoltaic cell assemblies 200 may comprise thin films arranged on the backing member attached to base member 120. The film used may be a CIGS film, which refers to the materials providing the film with its photovoltaic characteristic: copper-indium-gallium-diselenide. Such films are known in the solar cell industry, and are available from, for example, Global Solar Energy, Inc., 8500 South Rita Road, Tucson, Ariz., 85747, USA.

The foregoing embodiments have been provided solely to illustrate the structural and functional principles of the present invention and are not intended to be limiting. To the contrary, the present invention is intended to encompass all modifications, substitutions, alterations, and equivalents within the spirit and scope of the following claims.

What is claimed:

1. A photovoltaic module comprising:
an elongated base member having first and second extensions shaped to define an elongated support plane along ends thereof, the elongated support plane extending in a direction of elongation for the elongated base member; and
at least one photovoltaic cell assembly positioned at the ends of the elongated base member, extending generally along the elongated support plane;
wherein the elongated base member and the at least one photovoltaic cell assembly define a volume of space therein.

2. A photovoltaic module according to claim 1, wherein the first and second extensions each comprise a ledge extending along the direction of elongation, wherein the at least one photovoltaic cell assembly is supported by said ledge.

3. A photovoltaic module according to claim 1, wherein said elongated base member comprises polycarbonate, PVC, fiberglass, acrylic, aluminum, or other polymer or metal.

4. A photovoltaic module according to claim 1 further comprising an inverter at least partially contained within the volume of space, and electrically coupled to the at least one photovoltaic cell assembly.

5. A photovoltaic module according to claim 4, further comprising a light supported by said elongated base member and electrically coupled to the inverter.

6. A photovoltaic module according to claim 1, further comprising a transparent protective layer on a side of the photovoltaic cell assembly facing away from the elongated base member.

7. A photovoltaic module according to claim 1, wherein said base member comprises one or more pairs of apertures configured to receive a cable therethrough to slidably position said photovoltaic module thereon.

8. A photovoltaic module according to claim 1, further comprising at least one mounting support located on the elongated base member, configured to direct the at least one photovoltaic cell assembly at an angle with respect to an orientation of the at least one mounting support.

9. A photovoltaic module according to claim 8, wherein said at least one mounting support comprises one or more bolts, screws, needles or cable ties or twist ties, configured to secure the base member to a cable.

10. A photovoltaic module according to claim 8, wherein said base member comprises one or more apertures positioned along the first and/or second extensions such that the at least one mounting support may mount the photovoltaic module at a variety of angles.

11. A photovoltaic module comprising:
an elongated base member having a partially tubular configuration with a longitudinally extending opening;
an elongated photovoltaic cell assembly comprising a rigid backing member mounted to the base member to cover the longitudinally extending opening and form a tubular member with the base member, the photovoltaic cell assembly further comprising a plurality of photovoltaic elements mounted to an outer surface of the backing member and a transparent protective layer coated over the photovoltaic elements; and
at least one terminal coupled to the photovoltaic elements for conducting of electricity generated by the photovoltaic elements.

12. A photovoltaic module according to claim 11 further comprising an inverter at least partially contained between the elongated base member and the elongated photovoltaic cell assembly, and electrically coupled to the elongated photovoltaic cell assembly.

13. A photovoltaic module according to claim 12, further comprising a light supported by said elongated base member and electrically coupled to the inverter.

14. A photovoltaic module according to claim 11, further comprising at least one mounting support located on the elongated base member, configured to direct the elongated photovoltaic cell assembly at an angle with respect to an orientation of the at least one mounting support.

15. A photovoltaic cell system comprising:
a plurality of cables extending across a span;
a pair of support structures arranged in spaced apart relation from one another and configured to elevate and secure the plurality of cables above the span;
a plurality of elongated photovoltaic modules, each connected to and extending across at least two of said plurality of cables; and
one or more photovoltaic elements, each supported one or more of said plurality of elongated photovoltaic modules.

16. A photovoltaic cell system according to claim 15, wherein each of said plurality of cables comprises wire, cord, rope, or chain, and/or is constructed of metal, fiber, or synthetic materials.

17. A photovoltaic cell system according to claim 15, wherein each of said pair of support structures is associated with at least two of said plurality of cables.

18. A photovoltaic cell system according to claim 15, wherein at least one of said support structures comprise:
at least two columns extending generally vertically;
a cross beam connecting upper portions of the at least two columns and configured to elevate said plurality of cables; and
one or more braces angled towards said cross beam and/or said upper portions of said columns, configured to resist against a tension force of the plurality of cables on the at least two columns.

19. A photovoltaic cell system according to claim 18, wherein said support structures further comprise a footing associated with lower portions of said columns and/or said braces, configured to prevent movement of said support structures with respect to the span.

20. A photovoltaic cell system according to claim 15, wherein two or more of said plurality of elongated photovoltaic modules are in spaced apart relation along at least two of the plurality of cables across the span.

21. A photovoltaic cell system according to claim 15, further comprising one or more cross-braces extending across at least two of said plurality of cables not connected by said plurality of elongated photovoltaic modules.

22. A photovoltaic cell system according to claim 15 further comprising a cable tightener configured to adjust a tension on one or more of the plurality of cables.

23. A photovoltaic cell system according to claim 22, wherein said cable tightener comprises a winch.

24. A photovoltaic cell system according to claim 15, wherein each of the plurality of elongated photovoltaic modules is configured to angle each of the one or more photovoltaic elements in relation to the plurality of cables.

25. A photovoltaic cell system according to claim 24, wherein each of the plurality of elongated photovoltaic modules comprises a rounded base portion substantially surrounding a back portion of an associated one or more photovoltaic elements.
